(19) United States
(12) Patent Application Publication
(10) Pub. No.: US 2012/0316811 A1
(43) Pub. Date: Dec. 13, 2012

(54) APPARATUS AND METHOD FOR DETERMINING A REMAINING BATTERY LIFE OF A PORTABLE TERMINAL

(75) Inventors: Jong-Hun CHOI, Gyeonggi-do (KR); Hun-Woong YANG, Seoul (KR)

(73) Assignee: SAMSUNG ELECTRONICS CO., LTD., Gyeonggi-Do (KR)

(21) Appl. No.: 13/280,603

(22) Filed: Oct. 25, 2011

(30) Foreign Application Priority Data
Jun. 10, 2011 (KR) 10-2011-0056375

(51) Int. Cl. G01R 31/36

(52) U.S. Cl. 702/63

(57) ABSTRACT

An apparatus and method for determining a remaining battery life of a portable terminal are provided, in which a battery checker checks the remaining battery life, upon input of a power key is being input during a power-off state of the portable terminal, and a controller for checking and displaying of the remaining battery life during the power-off state of the portable terminal.

### CLAM OF PRIORITY

This application claims priority under 35 U.S.C. §119(a) to a Korean Patent Application filed in the Korean Intellectual Property Office on Jun. 10, 2011 and assigned Serial No. 10-2011-0056375 contents of which are incorporated herein by reference.

### BACKGROUND OF THE INVENTION

1. Field of the Invention

The present invention relates to an apparatus and method for determining the remaining life of a battery in a portable terminal, and more particularly, to an apparatus and method for determining the residual battery life of a portable terminal when the portable terminal is power off.

2. Description of the Related Art

The most challenging issue with portable terminals including smart phones is that the portable terminals can be used for a limited operation time due to limited battery capacity.

Accordingly, users increasingly need to check the power remained in the terminals. To avoid getting into running out of battery power, users should be able to detect the remaining battery power at any time.

In general, when a portable terminal is in a power-on state, a battery bar displayed on a display to indicate the percentage of battery left in the portable terminal.

If the portable terminal is power off, a user can transition the portable terminal to a charge mode by connecting it to a charger or a Universal Serial Bus (USB) cable, and the user reads the remaining battery life time from a battery icon.

During the power off mode, the user must boot the portable terminal without a charger or a USB cable coupled thereto for determining the remaining battery life. However, the booting takes tens of seconds or a few minutes after power-on in some terminals.

If a user wants to replace a discharged battery with another one, he or she must boot the portable terminal with the replacement in order to compare the remaining life of the existing battery with that of the replacement.

In case of a plurality of batteries, the user must boot the portable terminal with the individual batteries one by one to select a battery with the greatest residual quantity.

If the user powers off the portable terminal to save power, the user's booting of the portable terminal to check its remaining battery life contributes to unnecessary power consumption. Moreover, there is no way to check the remaining battery life when powering the portable terminal is not convenient in some instances.

### SUMMARY OF THE INVENTION

An aspect of embodiments of the present invention is to address at least the problems and/or disadvantages and to provide at least the advantages described below. Accordingly, an aspect of embodiments of the present invention is to provide an apparatus and method for determining the remaining battery time in a portable terminal when the portable terminal is in a power-off state.

Another aspect of embodiments of the present invention is to provide an apparatus and method for determining the remaining battery life in a portable terminal without booting the portable terminal.

A further aspect of embodiments of the present invention is to provide an apparatus and method for determining the percentage of remaining battery life in a portable terminal, without connecting a charger or a Universal Serial Bus (USB) cable to the portable terminal.

In accordance with an embodiment of the present invention, there is provided an apparatus for determining a residual battery quantity in a portable terminal, in which a battery checker checks a residual percentage of battery life, upon input of a power key while a predetermined key is being input in a power-off state of the portable terminal, and a controller controls checking and display of the remaining battery life, upon input of the power key while the predetermined key is being input in the power-off state of the portable terminal.

In accordance with another embodiment of the present invention, there is provided a method for determining a remaining battery time in a portable terminal, in which upon input of a power key while a predetermined key is being input in a power-off state of the portable terminal, a residual battery indication mode is transitioned to, and a residual battery life is checked and displayed during the residual battery indication mode.

In accordance with an embodiment of the present invention, a terminal for indicating a remaining battery life includes: a memory; and a processor operatively coupled to the memory, the processor configured to: determine the remaining battery life in response to a request during a power-off state of the portable terminal; and display a remaining percentage of the battery life in a display.

### BRIEF DESCRIPTION OF THE DRAWINGS

The above features and advantages of certain embodiments of the present invention will be more apparent from the following detailed description taken in conjunction with the accompanying drawings, in which:

FIG. 1 is a block diagram of a portable terminal according to an embodiment of the present invention;

FIG. 2 is a flowchart illustrating an operation for determining the residual quantity of a battery in the portable terminal according to an embodiment of the present invention; and

FIG. 3 is a view referred to for describing indication of a residual battery quantity in the portable terminal according to an embodiment of the present invention.

Throughout the drawings, the same drawing reference numerals will be understood to refer to the same elements, features and structures.

### DETAILED DESCRIPTION

Reference will now be made in detail to the preferred embodiments of the present invention with reference to the accompanying drawings. For the purposes of clarity and simplicity, a detailed description of a generally known function and structure of the present invention will be avoided as it obscure the subject matter of the present invention.

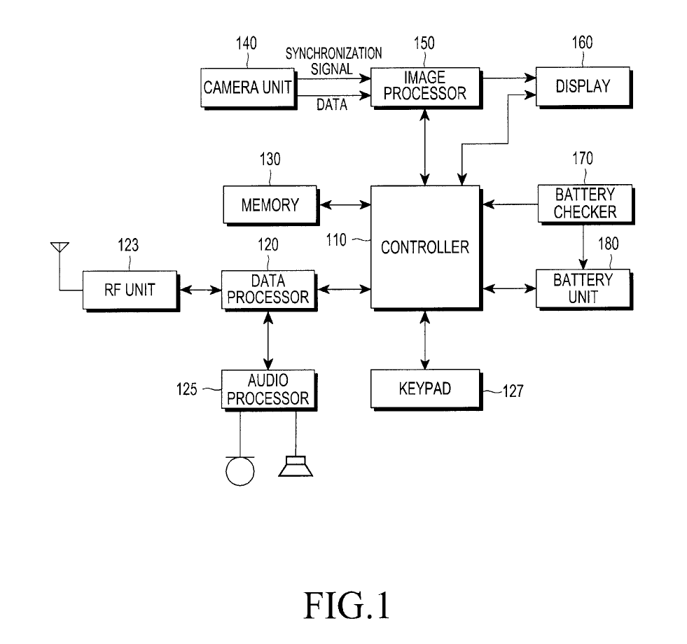

FIG. 1 is a block diagram of a portable terminal according to an embodiment of the present invention.

Referring to FIG. 1, a Radio Frequency (RF) unit 123 performs a wireless communication function for the portable terminal. The RF unit 123 includes an RF transmitter for upconverting the frequency of a transmission signal and amplifying the upconverted transmission signal and an RF receiver for low-noise-amplifying a received signal and downconverting the frequency of the low-noise-amplified signal.

A data processor 120 includes a transmitter for encoding and modulating the transmission signal and a receiver for demodulating and decoding the received signal. That is, the data processor 120 may include a MODEM and a CODEC. The CODEC includes a data CODEC for processing packet data and an audio CODEC for processing an audio signal such as voice.

An audio processor 125 reproduces a received audio signal output from the audio CODEC of the data processor 120 or transmits a transmission audio signal generated from a microphone to the audio CODEC of the data processor 120.

A memory 130 may include a program memory and a data memory. The program memory may store programs required to control typical operations of the portable terminal and a program required for determining the battery power of the portable terminal without booting the portable terminal.

A keypad 127 includes alphanumerical keys for inputting digits and characters and function keys for setting various functions.

In accordance with the embodiment of the present invention, the keypad 127 further includes a power key and a predetermined key for transitioning the portable terminal to a residual battery indication mode during a power-off state of the portable terminal. The predetermined key may be an existing key such as a home key, a volume key, or a capture key, or a separately procured key in the portable terminal.

A controller 110 provides overall control to the portable terminal.

In accordance with the embodiment of the present invention, upon input of the power key while the predetermined key is being input during the power-off state of the portable terminal, the controller 110 enters into the residual battery indication mode. In the residual battery indication mode, the controller 10 controls activation of only a battery checker 170 for checking the remaining battery life and displays it in a display 160. A general portable terminal can display the remaining battery life with bars using the battery checker.

The controller 110 has a User Interface (UI) function for displaying the remaining battery life on the display 160 in the residual battery indication mode in the embodiment of the present invention.

In addition, the controller 110 may have a battery check function for checking the remaining battery time during the residual battery indication mode according to an embodiment of the present invention. In this case, the battery checker 170 may not be provided in the portable terminal.

Upon receipt of the power key while the predetermined key is being input during the power-off state of the portable terminal, the battery checker 170 checks the residual time of a battery unit 180 and the battery unit 180 supplies power to the portable terminal. And, the portable terminal is turned on and the battery check unit and the display unit are also activated at the same time by pushing only another predetermined key, without pushing the power key. When simultaneously pushing the power key and another predetermined key, the portable terminal is turned on by pushing the power key, and only the battery check unit and display unit are activated by pushing another predetermined key.

A camera unit 140 includes a camera sensor for capturing an image and converting the captured optical signal to an electrical signal, and a signal processor for converting the analog image signal captured through the camera sensor to digital data. Herein, the camera sensor is assumed to be a Charge Coupled Device (CCD) or Complementary Metal Oxide Semiconductor (CMOS) sensor and the signal processor may be configured into a Digital Signal Processor (DSP). The camera sensor and the signal processor may be incorporated into a single device or separately configured.

An image processor 150 performs Image Signal processing (ISP) to display an image signal received from the camera unit 140 on a display 160. The ISP involves functions such as gamma correction, interpolation, spatial change, image effects, image scaling. Auto White Balance (AWB), Auto Exposure (AE), Auto Focus (AF), etc. Therefore, the image processor 150 processes the image signal received from the camera unit 140 on a frame basis and outputs the frame image data according to the characteristics and size of the display 160. The image processor 150 includes a video CODEC for compressing frame image data to be displayed on the display 160 in a predetermined scheme or decompressing compressed frame image data to the original frame image data. The video CODEC may be a JPEG CODEC, an MPEG4 CODEC, or a Wavelet CODEC. It is assumed herein that the image processor 150 is equipped with an On Screen Display (OSD) function, and the image processor 150 may output OSD data according to the size of a displayed screen under the control of the controller 110.

The display 160 displays the image signal received from the image processor 150 on a screen and also displays user data received from the controller 110. The display 160 may be configured with a Liquid Crystal Display (LCD). In this case, the display 160 may include an LCD controller, a memory for storing image data, and an LCD device. If the LCD is configured into a touch screen, it may serve as an input unit. Thus, the display 160 may display the same keys as those of the keypad 127.

According to the embodiment of the present invention, the display 160 displays a residual battery time during the residual battery indication mode.

The display 160 may further display a booting menu for transitioning to a booting mode and an end menu for powering off the portable terminal, together with the residual battery quantity in the residual battery quantity indication mode.

If the display 160 operates in a touch screen fashion, the booting menu or the end menu may be selected by touching the display 160. Otherwise, the controller 110 may control selection of the booting menu or the end menu by activating the keypad 127.

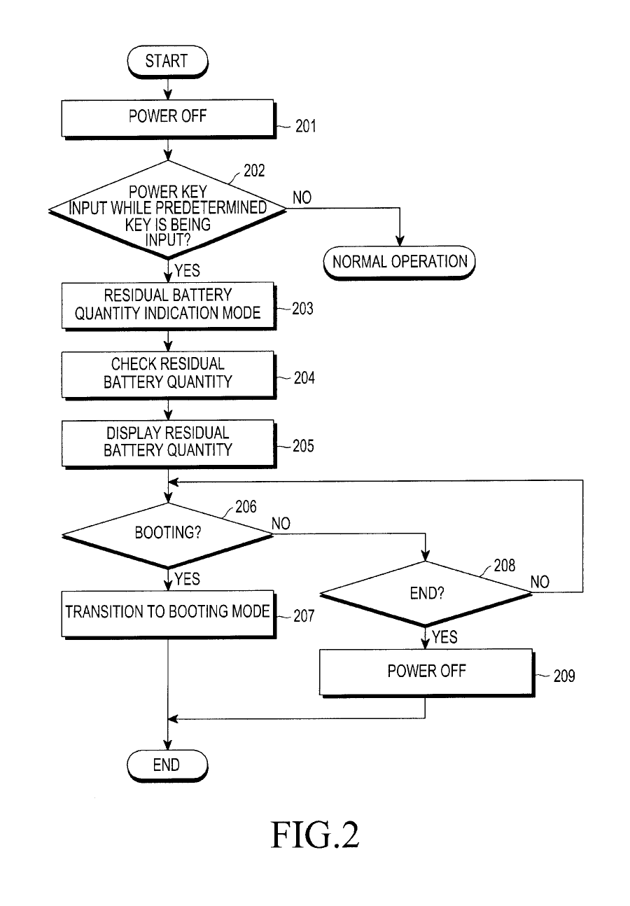

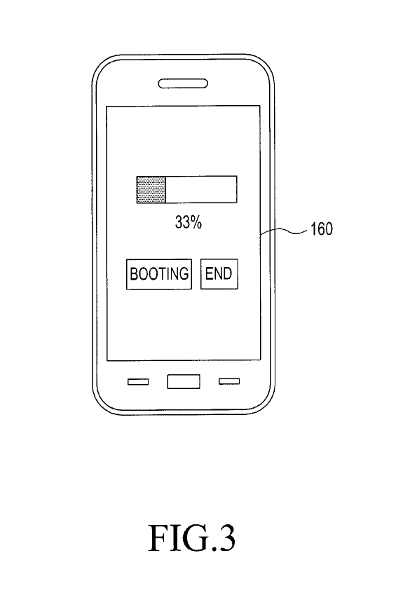

Now a detailed description will be given of an operation for determining and displaying a residual battery quantity in the portable terminal with reference to FIGS. 2 and 3.

FIG. 2 is a flowchart illustrating an operation for determining the remaining percentage of battery life or time in the portable terminal according to an embodiment of the present invention.

Referring to FIG. 2, the portable terminal is power off in step 201. Upon receipt of the power key while the predetermined key is being input in the power-off state in step 202, the controller 110 transitions to the residual battery indication mode in step 203.

In the residual battery quantity mode, the controller 110 controls activation of only the battery checker 170 for checking a remaining battery life and the display 180 for displaying the remaining battery time.

The activated battery checker 170 checks a current remaining battery life and transmits the information to the controller 110 in step 204.

Upon receipt of the information about the current remaining battery life, the controller 110 controls the activated display 160 to display the remaining battery life in step 205.

Specifically, the controller 110 may indicate the remaining battery life in various manners, for example, in the form of a battery bar or a value on the display 160.

The controller 110 may further display a booting menu for transitioning to the booting mode and an end menu for powering off the portable terminal, together with the remaining battery life on the display 160.

Upon selection of the booting menu on the display 160 by touch in step 206, the controller 110 transitions the portable terminal to the booting mode in step 207. On the other hand, upon selection of the end menu on the display 160 by touch in step 208, the controller 110 powers off the portable terminal in step 209.

FIG. 3 is a view referred to for describing indication of a residual battery quantity in the portable terminal according to an embodiment of the present invention.

Referring to FIG. 3, a current remaining battery life is indicated by a battery bar on the display 160. Together with the battery bar, a booting menu for entering into the booting mode and an end menu for powering off the portable terminal are also displayed.

A user can identify the current remaining battery life without booting the portable terminal by the operation illustrated in FIG. 2.

If the user has a plurality of batteries, he or she may check the remaining life of a current battery and then power off the portable terminal by selecting the end menu. Then, the user may install another battery to the portable terminal and can also check the residual quantity of the replacement by the operation of FIG. 2.

Meanwhile, after checking the current remaining battery life, the user may directly switch the portable terminal to the booting mode by powering on the portable terminal through a selection of the booting menu.

As is apparent from the above description, the apparatus and method for determining a remaining battery life of a portable terminal according to the present invention enables a user to readily identify the percentage of remaining battery life without booting the portable terminal during the power off mode.

The above-described methods according to the present invention can be implemented in hardware, firmware or as software or computer code that can be stored in a recording medium such as a CD ROM, an RAM, a floppy disk, a hard disk, or a magneto-optical disk or computer code downloaded over a network originally stored on a remote recording medium or a non-transitory machine readable medium and to be stored on a local recording medium, so that the methods described herein can be rendered in such software that is stored on the recording medium using a general purpose computer, or a special processor or in programmable or dedicated hardware, such as an ASIC or FPGA. As would be understood in the art, the computer, the processor, microprocessor controller or the programmable hardware include memory components, e.g., RAM, ROM, Flash, etc. that may store or receive software or computer code that when accessed and executed by the computer, processor or hardware implement the processing methods described herein. In addition, it would be recognized that when a general purpose computer accesses code for implementing the processing shown herein, the execution of the code transforms the general purpose computer into a special purpose computer for executing the processing shown herein.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. An apparatus for determining a remaining battery life of a portable terminal, comprising:
a battery checker for checking the remaining battery life in response to a request during a power-off state of the portable terminal; and
a controller for determining and displaying a remaining percentage of the battery life.

2. The apparatus of claim 1, further comprising a display for displaying the remaining percentage of the battery life.

3. The apparatus of claim 1, wherein upon input of a predetermined during the power-off state of the portable terminal, the controller controls transitioning of the portable terminal to a residual battery indication mode and controls activation of only the battery checker.

4. The apparatus of claim 1, wherein, in response to selection of booting while displaying the remaining percentage of the battery life, the controller controls transitioning of the portable terminal to a booting mode.

5. The apparatus of claim 1, wherein, in response to a selection of end while displaying the remaining percentage of the battery life, the controller powers off the portable terminal.

6. A method for determining a remaining battery life in a portable terminal, the method comprising:
transitioning to a residual battery indication mode, in response to predetermined key during a power-off state of the portable terminal; and
checking and displaying a remaining percentage of battery life during the residual battery indication mode.

7. The method of claim 6, further comprising, upon a selection of booting while displaying the remaining percentage of the battery life, transitioning the portable terminal to a booting mode.

8. The method of claim 6, further comprising, upon a selection of end while displaying the remaining percentage of the battery life, powering off the portable terminal.
